(19) United States
(12) Patent Application Publication
(10) Pub. No.: US 2016/0048087 A1
(43) Pub. Date: Feb. 18, 2016

(54) SCANNER AND METHOD FOR PERFORMING EXPOSURE PROCESS ON WAFER

(71) Applicant: MACRONIX International Co., Ltd., Hsinchu (TW)

(72) Inventors: Chin-Cheng Yang, Hsinchu (TW); Chi-Hao Huang, Hsinchu (TW)

(21) Appl. No.: 14/457,982

(22) Filed: Aug. 12, 2014

(51) Int. Cl. G03F 7/20

(52) U.S. Cl. CPC G03F 7/70708; G03F 7/70775

(57) ABSTRACT

A scanner and a method for performing an exposure process through a photomask on a wafer are provided. The exposure process includes an alignment step and an exposure step. The method includes the steps of moving a wafer table to align the wafer with an alignment apparatus, wherein the wafer table includes at least one chuck hole to attach the wafer to the wafer table by vacuum chucking, detecting an actual position of each of a plurality of alignment marks on the wafer, calculating an index value based on a difference between a predicted position and the actual position of each alignment mark, adjusting a vacuum pressure of the at least one chuck hole in the alignment step when the index value is larger than a first threshold value, and finishing the exposure process when the index value is smaller than or equal to the first threshold value.

### BACKGROUND OF THE INVENTION

1. Field of the Invention

The present invention relates to an exposure process. More particularly, the present invention relates to a scanner and a method for performing an exposure process through a photomask on a wafer.

2. Description of the Related Art

Exposure is an essential part of photolithography process for manufacturing semiconductor devices. An exposure process includes an alignment step and an exposure step. In the alignment step, the wafer is aligned with an alignment apparatus of the scanner. When there is a previous layer of image already formed on the wafer, the previous layer has to be very precisely aligned with the alignment apparatus to ensure that the current layer of image will be formed on the wafer at the desired position. In the overlay measurement step after the photolithography process, the overlay mark location between currently layer and previous layer is measured for checking the alignment performance of the exposure step.

However, sometimes the actual position of the current layer formed on the wafer is not the desired position. In this situation, differences between the positions of the overlay marks of the previous layer and the positions of the overlay marks of the current layer can be calculated and then amounts of compensation for the current layer along the X axis and the Y axis can be determined based on the differences of the positions. Next, the current layer is reworked, which means washing off the photoresist of the current layer and then re-form the current layer on the wafer in another photolithography process. By aligning the wafer and the alignment apparatus according to the amounts of compensation, the current layer can be re-formed on the desired position.

The precision of the alignment and the effect of the compensation can be expressed by residual vectors. The residual vectors can be calculated by deducting the amounts of compensation from the differences of the positions. The residual vectors represent a part of the differences of the positions that is not compensated. The smaller the residual vectors, the better the alignment and the better the effect of the compensation.

FIG. 1 shows a flat wafer 120 attached to a wafer table 110 by vacuum chucking. Such a flat wafer is ideal for the exposure process. The resultant residual vectors are very small and negligible. However, non-ideal temperature, non-ideal vacuum pressure, stresses of films, and other factors of the process can deform a wafer. A deformed wafer can become convex or concave, or convex at a part and concave at another part. FIG. 2 shows a convex wafer 220 attached to the wafer table 110. FIG. 3 shows a concave wafer 320 attached to the wafer table 110. Such a deformed wafer generates large and chaotic residual vectors. For example, FIG. 4 is a schematic diagram showing residual vectors of a deformed wafer 400 calculated in an overlay step of a conventional exposure process. Each arrow in FIG. 4 represents a residual vector. As shown in FIG. 4, the residual vectors form a complex pattern of various directions and magnitudes, which complicates the compensation. Even when the position of the current layer of a deformed wafer can be compensated, the current layer has to be reworked.

### SUMMARY OF THE INVENTION

Accordingly, the present invention is directed to a scanner and a method for performing an exposure process, which are capable of improving the alignment of the current layer without reworking the current layer.

According to an embodiment of the present invention, a scanner for performing an exposure process through a photomask on a wafer is provided. The exposure process includes an alignment step and an exposure step. The scanner includes an alignment apparatus, a wafer table and a controller. The wafer table includes at least one chuck hole to attach the wafer to the wafer table by vacuum chucking. The controller moves the wafer table to align the wafer with the alignment apparatus, detects an actual position of each of a plurality of alignment marks on the wafer, calculates an index value based on a difference between a predicted position and the actual position of each alignment mark, adjusts a vacuum pressure of the at least one chuck hole in the alignment step when the index value is larger than a first threshold value, controls the scanner to finish the exposure process when the index value is smaller than or equal to the first threshold value.

According to another embodiment of the present invention, a method for performing an exposure process through a photomask on a wafer is provided. The exposure process includes an alignment step and an exposure step. The method includes the steps of moving a wafer table to align the wafer with an alignment apparatus, wherein the wafer table includes at least one chuck hole to attach the wafer to the wafer table by vacuum chucking, detecting an actual position of each of a plurality of alignment marks on the wafer, calculating an index value based on a difference between a predicted position and the actual position of each alignment mark, adjusting a vacuum pressure of the at least one chuck hole in the alignment step when the index value is larger than a first threshold value, and finishing the exposure process when the index value is smaller than or equal to the first threshold value.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram showing a flat wafer on a conventional wafer table.

FIG. 2 is a schematic diagram showing a convex wafer on a conventional wafer table.

FIG. 3 is a schematic diagram showing a concave wafer on a conventional wafer table.

FIG. 4 is a schematic diagram showing residual vectors of a deformed wafer calculated in an overlay measurement step after a conventional photolithography process.

FIG. 5 is a schematic diagram showing a scanner for performing an exposure process according to an embodiment of the present invention.

FIG. 6 is a schematic diagram showing residual vectors of a deformed wafer calculated in an alignment step according to an embodiment of the present invention.

FIG. 7 is a flow chart showing a method for performing an exposure process according to an embodiment of the present invention.

FIG. 8 is a schematic diagram showing a wafer table according to an embodiment of the present invention.

FIG. 9 is a schematic diagram showing a wafer table according to another embodiment of the present invention.

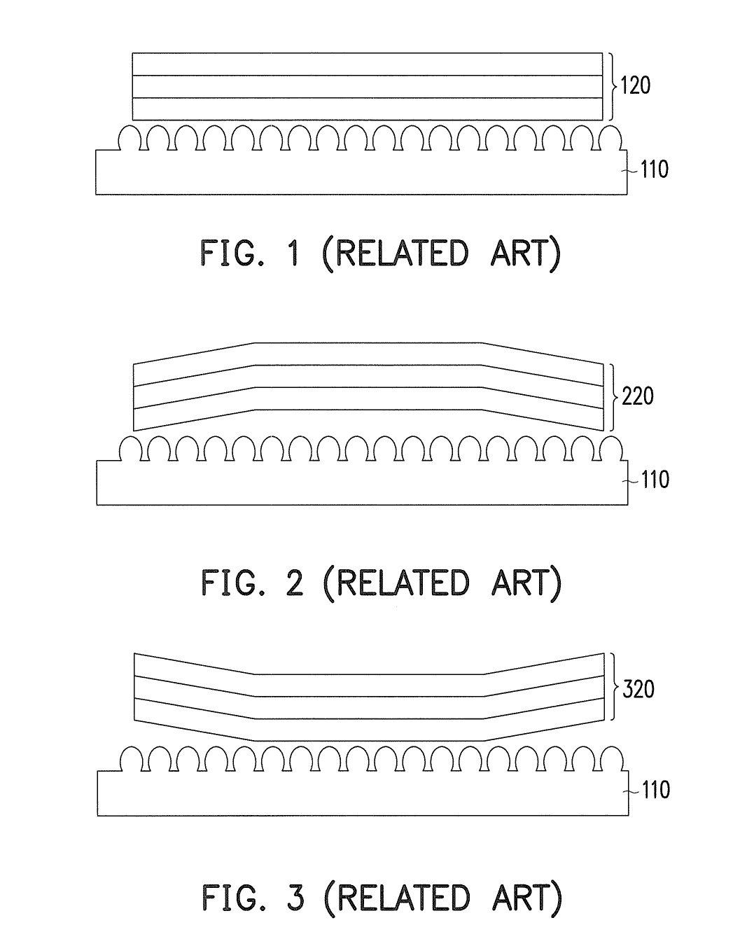

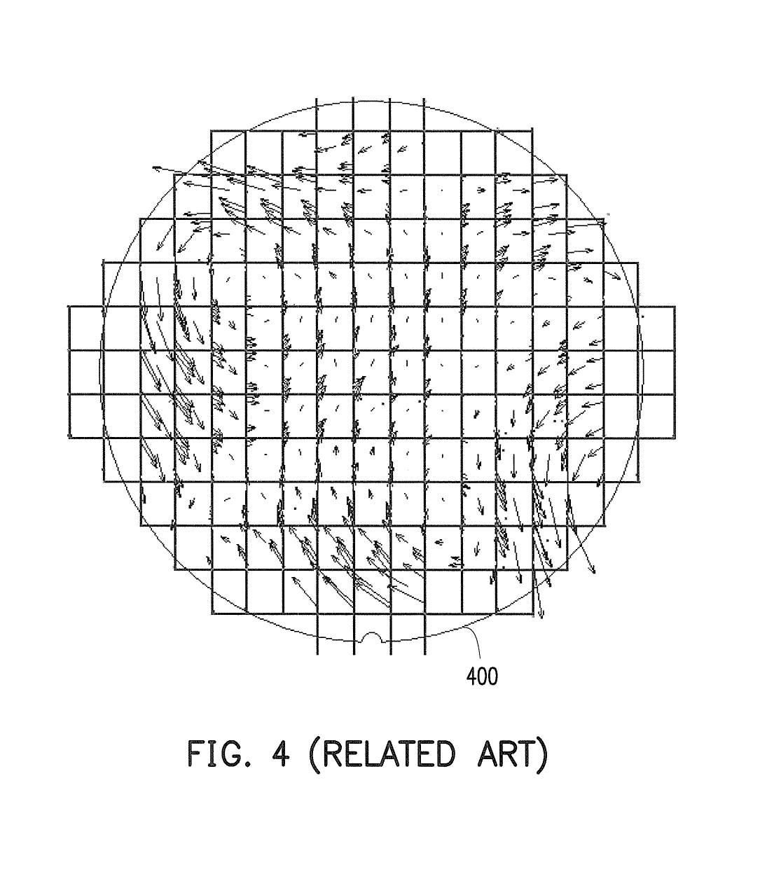

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

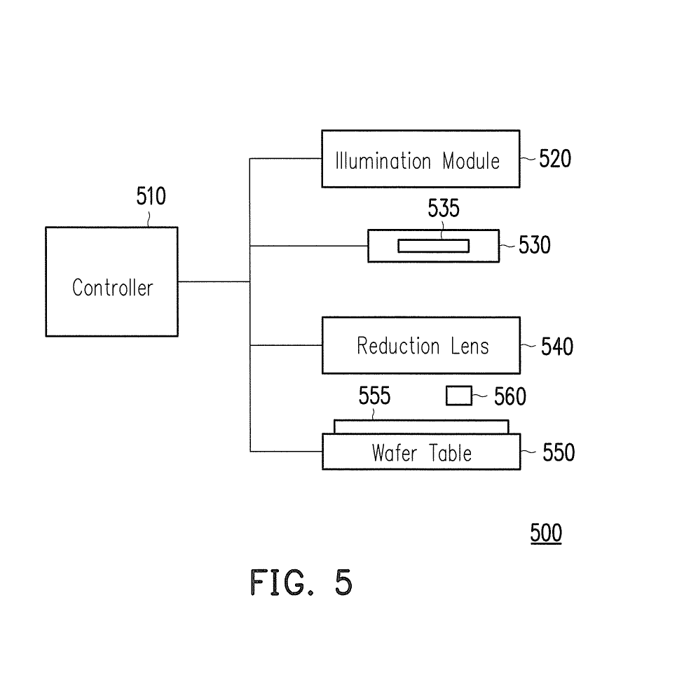

FIG. 5 is a schematic diagram showing a scanner 500 for performing an exposure process according to an embodiment of the present invention. The scanner 500 includes a controller 510, an illumination module 520, a photomask holder 530, a reduction lens 540, a wafer table 550, and an alignment apparatus 560. The photomask holder 530 is configured to hold a photomask 535. The wafer table 550 includes at least one chuck hole to attach a wafer 555 to the wafer table 550 by vacuum chucking. The alignment apparatus 560 serves as a reference point for the alignment of the wafer 555. The controller 510 is coupled to the illumination module 520, the photomask holder 530, the reduction lens 540, and the wafer table 550.

The controller 510 controls the illumination module 520, the photomask holder 530, the reduction lens 540, and the wafer table 550 to perfoim an exposure process through the photomask 535 on the wafer 555. The controller 510 moves the wafer table 550 to align the wafer 555 with the alignment apparatus 560. The controller 510 moves the photomask 535 to align with the alignment apparatus 560 before the exposure step. The controller 510 controls the illumination module 520 to emit light. The light passes through the photomask 535 and the reduction lens 540. The reduction lens 540 focuses and reduces the pattern on the photomask 535 and projects the pattern onto the wafer 555 to form an image that is used to form elements of the integrated circuit (IC).

The controller 510 may calculate an index value to express how well the wafer is aligned with the alignment apparatus 560. For example, some existing scanners in the market can provide a residual of position index (ROPI). The controller 510 may calculate the ROPI to serve as the aforementioned index value in the alignment step of the exposure process. When there are alignment marks of the previous layer or the previous layers formed on the wafer, the controller 510 may calculate the differences between actual positions of the alignment marks and predicted positions (namely, desired positions) of the alignment marks. The predicted positions of the alignment marks may be input into the scanner 500 in advance. The controller 510 may determine amounts of compensation along the X axis and the Y axis for the actual positions of the alignment marks based on the differences. The controller 510 may calculate a residual vector for each alignment mark by deducting the amounts of compensation from the difference of the two positions of the alignment mark. Next, the controller 510 may calculate the ROPI based on mean and 3-sigma of the elements of the tuples of the residual vectors. Since calculating the ROPI is a conventional technique, the details are omitted here for brevity.

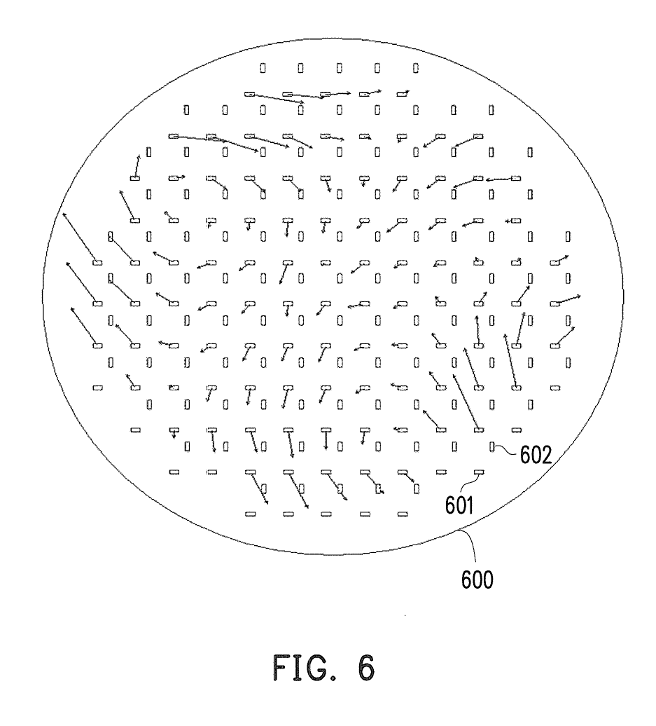

Similar to the residual vectors calculated in the overlay measurement step after photolithography process in the description of the related art, the residual vectors for the ROPI and the ROPI itself calculated in the alignment step can indicate the precision of the alignment of a wafer. When a wafer is very precisely aligned, the ROPI is small and the residual vectors are small and uniform. When a wafer is not precisely aligned, the ROPI is large and the residual vectors are large and chaotic. For example, FIG. 6 is a schematic diagram showing residual vectors of a deformed wafer 600 calculated in the alignment step according to an embodiment of the present invention. There are many alignment marks formed on the wafer 600, such as the two alignment marks 601 and 602. Each arrow in FIG. 6 depicts a residual vector for calculating the ROPI. The wafer 600 is not precisely aligned because of wafer deformation. Therefore, the residual vectors in FIG. 6 exhibit diverse magnitudes and directions.

The ROPI is just an example of the aforementioned index value. In another embodiment of the present invention, the controller 510 may calculate another kind of index value to serve as the indicator of the precision of the alignment of the wafer as long as the index value is correlated to the precision of the overlay measurement information of the wafer.

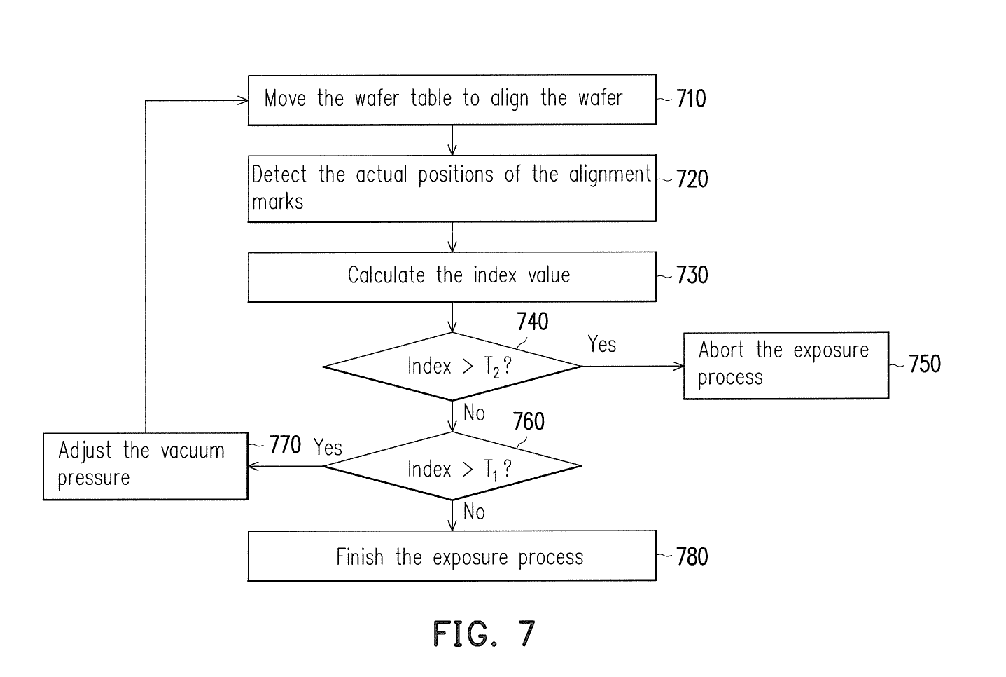

FIG. 7 is a flow chart showing a method for performing an exposure process according to an embodiment of the present invention. As discussed earlier, the exposure process includes an alignment step and an exposure step. The method shown in FIG. 7 may be executed by the controller 510 of the scanner 500. In step 710, the controller 510 moves the wafer table 550 to align the wafer 555 with the alignment apparatus 560. Alternatively, the controller 510 may move the wafer table 550 and the photomask holder 530 with respect to each other to align the wafer 555 with the alignment apparatus. When there is a previous layer already formed on the wafer 555, the controller 510 aligns the previous layer with the photomask 535 so that the current layer can be overlaid precisely with respect to the previous layer. The pattern of the photomask 535 will be reduced and projected into each grid of the grid pattern on the wafer 555.

When there is a previous layer on the wafer 555, the controller 510 can use alignment marks of the previous layer to calculate the aforementioned index value. In step 720, the controller 510 detects the actual position of each of the alignment marks. In step 730, the controller 510 calculates the index value to serve as an indicator of the alignment based on the difference between the predicted position and the actual position of each alignment mark.

In step 740, the controller 510 compares the index value with a preset threshold value T₂. When the index value is larger than the threshold value T₂, in step 750 the controller 510 controls the scanner 500 to abort the exposure process. This means the alignment of the wafer 555 is too imprecise to be corrected automatically and this problem has to be solved manually. When the index value is smaller than or equal to the threshold value T₂, the flow proceeds to step 760.

In step 760, the controller 510 compares the index value with another preset threshold value T₁. The threshold value T₁ is smaller than the threshold value T₂. When the index value is larger than the threshold value T₁, in step 770 the controller 510 adjusts the vacuum pressure of the at least one chuck hole of the wafer table 550, and then the flow returns to step 710. By adjusting the vacuum pressure and then repeating steps 710, 720 and 730, there is a chance that the adjusted vacuum pressure can keep the index value smaller than or equal to the threshold value T₁. For example, when the wafer 555 is deformed and convex, like the wafer 220 in FIG. 2, the controller 510 can probably flatten the wafer 555 by increasing the vacuum pressure. When the wafer 555 is deformed and concave, like the wafer 320 in FIG. 3, the controller 510 can probably flatten the wafer 555 by decreasing the vacuum pressure. When the index value is smaller than or equal to the threshold value T₁, in step 780 the controller 510 controls the scanner 500 to finish the entire exposure process.

Please note that the controller 510 executes steps 710-770 in the alignment step of the exposure process. In other words, each step of the method shown in FIG. 7 except step 780 is a part of the alignment step of the exposure process. When the alignment of the wafer 555 is imprecise due to wafer deformation, tilted wafer table, or other factors, the index value enables the controller 510 to identify the alignment problem in the alignment step and the controller 510 can solve the alignment problem by adjusting the vacuum pressure in the alignment step. Since the alignment problem can be solved before the overlay measurement step, the scanner and the method provided by the present invention are capable of improving the alignment of the current layer without reworking the current layer. This can save the time and the cost of the exposure process.

In an embodiment of the present invention, the wafer table 550 includes a plurality of chuck holes and the chuck holes share the same vacuum pressure. In other words, each chuck hole has the same vacuum pressure. When the controller 510 adjusts the vacuum pressure in step 770, the controller 510 may adjust the vacuum pressure according to a preset sequence of a plurality of candidate pressures. For example, assume the current vacuum pressure is P₀ and the preset sequence includes four candidate pressures P₁, P₂, P₃ and P₄. P₁ is P₀ increased by 10%. P₂ is P₀ increased by 20%. P₃ is P₀ decreased by 10%. P₄ is P₀ decreased by 20%. Steps 710, 720, 730, 740, 760 and 770 constitute a loop. The controller 510 may set the vacuum pressure of the chuck holes to be P₁ in the first iteration of the loop, and then set the vacuum pressure of the chuck holes to be P₂ in the second iteration of the loop, and then set the vacuum pressure of the chuck holes to be P₃ in the third iteration of the loop, and then set the vacuum pressure of the chuck holes to be P₄ in the fourth iteration of the loop. Eventually, when the flow leaves the loop and proceeds to step 780, the controller 510 sets the vacuum pressure of the chuck holes to be the first candidate pressure that keeps the index value smaller than or equal to the threshold value T₁.

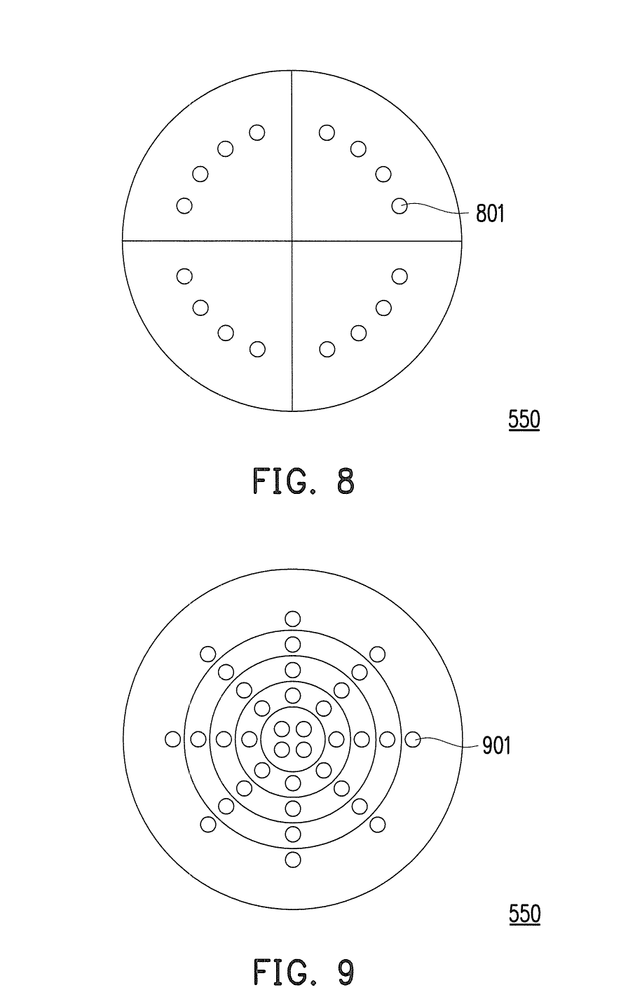

In another embodiment of the present invention, the wafer table 550 includes a plurality of chuck holes arranged into a plurality of clusters. Each cluster may include one or more chuck holes. For example, FIG. 8 is a schematic diagram showing the wafer table 550 according to an embodiment of the present invention. The wafer table 550 includes 16 chuck holes, such as the chuck hole 801. The wafer table 550 is divided into four quadrants. Each quadrant is a cluster including four chuck holes. For another example, FIG. 9 is a schematic diagram showing the wafer table 550 according to another embodiment of the present invention. In this embodiment, the wafer table 550 includes 36 chuck holes, such as the chuck hole 901. The wafer table 550 is divided into five concentric circles. Each circle is a cluster. The innermost cluster includes four chuck holes, while each of the other clusters includes eight chuck holes.

When the chuck holes are organized into clusters, the at least one chuck hole in each cluster shares the same vacuum pressure corresponding to the cluster. The controller 510 adjusts the vacuum pressure of each cluster independently in step 770. For example, assume the chuck pressure corresponding to the first cluster is P₁ and the chuck pressure corresponding to the first cluster is P₂. The vacuum pressure of each chuck hole in the first cluster is P₁ and the vacuum pressure of each chuck hole in the second cluster is P₂. The controller 510 adjusts P₁ and P₂ independently in step 770.

The controller 510 may adjust the vacuum pressures of the clusters according to a preset sequence of a plurality of candidate sets. Each candidate set may include a plurality of candidate pressures. The number of the candidate pressures in each candidate set is equal to the number of the clusters. Each candidate pressure in each candidate set is for setting the vacuum pressure of a cluster. The controller 510 may set the vacuum pressures of the clusters according to the first candidate set in the first iteration of the loop in FIG. 7, and then set the vacuum pressures of the clusters according to the second candidate set in the second iteration of the loop, and so on. Eventually, the controller 510 sets the vacuum pressures of the clusters according to the first candidate set that keeps the index value smaller than or equal to the threshold value T₁.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A scanner for performing an exposure process through a photomask on a wafer, wherein the exposure process comprises an alignment step and an exposure step, and the scanner comprising:
an alignment apparatus;
a wafer table, comprising at least one chuck hole to attach the wafer to the wafer table by vacuum chucking; and
a controller, moving the wafer table to align the wafer with the alignment apparatus, detecting an actual position of each of a plurality of alignment marks on the wafer, calculating an index value based on a difference between a predicted position and the actual position of each said alignment mark, adjusting a vacuum pressure of the at least one chuck hole in the alignment step when the index value is larger than a first threshold value, controlling the scanner to finish the exposure process when the index value is smaller than or equal to the first threshold value.

2. The scanner of claim 1, wherein the controller repeats the aligning of the wafer, the detecting of the actual positions, and the calculating of the index value in the alignment step after adjusting the vacuum pressure of the at least one chuck hole.

3. The scanner of claim 1, wherein the at least one chuck hole comprises a plurality of chuck holes sharing the same vacuum pressure.

4. The scanner of claim 1, wherein the controller adjusts the vacuum pressure according to a preset sequence of a plurality of candidate pressures, and the controller sets the vacuum pressure to be one said candidate pressure that keeps the index value smaller than or equal to the first threshold value.

5. The scanner of claim 1, wherein the at least one chuck hole comprises a plurality of chuck holes arranged into a plurality of clusters, each said cluster comprises at least one of the chuck holes, the at least one chuck hole in each said cluster shares a same vacuum pressure corresponding to the said cluster, and the controller adjusts the vacuum pressure of each said cluster independently.

6. The scanner of claim 5, wherein the controller adjusts the vacuum pressures of the clusters according to a preset sequence of a plurality of candidate sets, each said candidate set comprises a candidate pressure for each said cluster, and the controller sets the vacuum pressures of the clusters according to one said candidate set that keeps the index value smaller than or equal to the first threshold value.

7. The scanner of claim 1, wherein the controller controls the scanner to abort the exposure process in the alignment step when the index value is larger than a second threshold value.

8. A method for performing an exposure process through a photomask on a wafer, wherein the exposure process comprises an alignment step and an exposure step, and the method comprising:
moving a wafer table to align the wafer with an alignment apparatus, wherein the wafer table comprises at least one chuck hole to attach the wafer to the wafer table by vacuum chucking;
detecting an actual position of each of a plurality of alignment marks on the wafer;
calculating an index value based on a difference between a predicted position and the actual position of each said alignment mark;
adjusting a vacuum pressure of the at least one chuck hole in the alignment step when the index value is larger than a first threshold value; and
finishing the exposure process when the index value is smaller than or equal to the first threshold value.

9. The method of claim 8, further comprising:
repeating the aligning of the wafer, the detecting of the actual positions, and the calculating of the index value in the alignment step after adjusting the vacuum pressure of the at least one chuck hole.

10. The method of claim 8, wherein the at least one chuck hole comprises a plurality of chuck holes sharing the same vacuum pressure.

11. The method of claim 8, further comprising:
adjusting the vacuum pressure according to a preset sequence of a plurality of candidate pressures; and
setting the vacuum pressure to be one said candidate pressure that keeps the index value smaller than or equal to the first threshold value.

12. The method of claim 8, wherein the at least one chuck hole comprises a plurality of chuck holes arranged into a plurality of clusters, each said cluster comprises at least one of the chuck holes, the at least one chuck hole in each said cluster shares a same vacuum pressure corresponding to the said cluster, and the vacuum pressure of each said cluster is adjusted independently.

13. The method of claim 12, further comprising:
adjusting the vacuum pressures of the clusters according to a preset sequence of a plurality of candidate sets, wherein each said candidate set comprises a candidate pressure for each said cluster; and
setting the vacuum pressures of the clusters according to one said candidate set that keeps the index value smaller than or equal to the first threshold value.

14. The method of claim 8, further comprising:
aborting the exposure process in the alignment step when the index value is larger than a second threshold value.
